(19) United States
(12) Patent Application Publication
(10) Pub. No.: US 2025/0374537 A1
(43) Pub. Date: Dec. 4, 2025

(54) SEMICONDUCTOR DEVICE AND METHOD OF FORMING THE SAME

(71) Applicant: MICRON TECHNOLOGY, INC., BOISE, ID (US)

(72) Inventors: Naokazu Murata, Hiroshima (JP); AKIRA KANEKO, Hiroshima (JP); KEISUKE SHIMADA, Hiroshima (JP); ATSUSHI MAEKAWA, Hiroshima (JP); RYOTA MIYAHARA, Hiroshima (JP)

(73) Assignee: MICRON TECHNOLOGY, INC., Boise, ID (US)

(21) Appl. No.: 19/210,752

(22) Filed: May 16, 2025

Related U.S. Application Data
(60) Provisional application No. 63/653,640, filed on May 30, 2024.

(51) Int. Cl. H10B 12/00

(52) U.S. Cl. CPC H10B 12/50; H10B 12/09; H10B 12/315

(57) ABSTRACT

An example apparatus includes a memory cell capacitor; a memory cell transistor having diffusion regions; a redistribution structure coupled between one of the diffusion regions of the memory cell transistor and the memory cell capacitor; a first wiring; a peripheral transistor having diffusion regions; and a contact plug connected between one of the diffusion regions of the peripheral transistor and the first wiring. The first wiring is on a layer higher than that the redistribution structure is on.

### CROSS-REFERENCE TO RELATED APPLICATIONS

This application claims the filing benefit of U.S. Provisional Application No. 63/653,640, filed May 30, 2024. This application is incorporated by reference herein in its entirety and for all purposes.

### BACKGROUND

In recent years, in semiconductor devices such as Dynamic Random Access Memories, the distances between conductive parts provided inside the devices have been reduced in order to enhance the degree of integration. Due to variations in alignment, dimensions of conductive parts, etc. during a manufacturing process, short-circuits or opens may occur in adjacent conductive parts.

### BRIEF DESCRIPTION OF THE DRAWINGS

FIG. 1A is a plan view showing a schematic configuration of a part of a semiconductor device according to an embodiment. FIG. 1B is a plan view showing a schematic configuration of a memory cell portion of the semiconductor device according to the embodiment. FIG. 1C is a diagram showing an equivalent circuit of a memory cell of the semiconductor device according to the embodiment.

FIG. 2A is a longitudinal sectional view showing a schematic configuration of a peripheral circuit region of the semiconductor device according to the embodiment. FIG. 2B is a longitudinal sectional view showing a schematic configuration of a memory cell region of the semiconductor device according to the embodiment, and is a longitudinal sectional view showing a schematic configuration of a portion along an A-A line of FIG. 1B. FIGS. 2A and 2B are diagrams showing a method for manufacturing the semiconductor device according to the embodiment, and are diagrams showing an example of a schematic configuration at an exemplary process stage following FIGS. 11A and 13.

FIG. 3A and FIG. 3B are diagrams showing the method for manufacturing the semiconductor device according to the embodiment, and are diagrams showing an example of a schematic configuration at an exemplary process stage. FIG. 3B is a longitudinal sectional view showing the schematic configuration of the portion along the A-A line of FIG. 1B.

FIGS. 4A and 4B to FIGS. 11A and 11B are diagrams showing the method for manufacturing the semiconductor device according to the embodiment in order of steps. FIGS. 4A and 4B are diagrams showing an example of a schematic configuration at an exemplary process stage following FIGS. 3A and 3B. FIGS. 4B, 5B, 6B, 7B, 8B, 9B, 10B, and 11B are longitudinal sectional views showing the schematic configuration of the portion along line A-A of FIG. 1B.

FIG. 12 and FIG. 13 are diagrams showing the method for manufacturing the semiconductor device according to the embodiment in order of steps. FIG. 12 is a diagram showing an example of a schematic configuration at an exemplary process stage following FIG. 11B. FIG. 13 is a diagram showing an example of a schematic configuration at an exemplary process stage following FIG. 12. FIG. 12 and FIG. 13 are longitudinal sectional views showing the schematic configuration of the portion along the A-A line of FIG. 1B.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device according to an embodiment will be described below with reference to the drawings. In the following description, a dynamic random access memory (DRAM) will be described as an example of the semiconductor device. In the description of the embodiment, common or related elements, or substantially the same elements are denoted by the same reference signs, and the description thereof will be omitted. In the following figures, the dimensions and dimension ratios of the respective portions in the respective figures are not necessarily matched with the dimensions and dimension ratios in the embodiment. Furthermore, in the following description, a Y-direction is perpendicular to an X-direction. The X-direction and the Y-direction may be referred to as horizontal directions. A Z-direction is perpendicular to an X-Y plane which is a plane of a semiconductor substrate, and may be referred to as a vertical direction. Furthermore, in the following description, an up-and-down direction and a left-right direction mean directions in each drawing when a semiconductor substrate is placed on a bottom side.

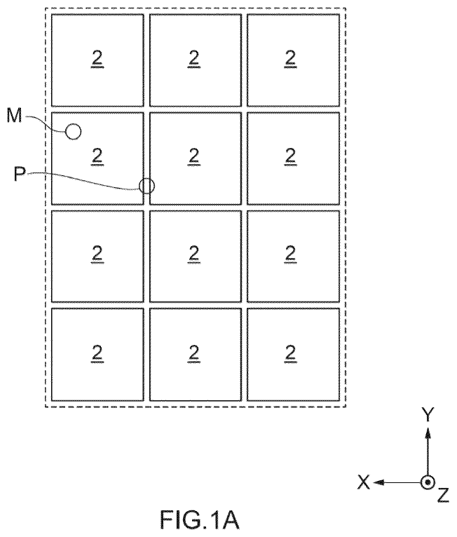

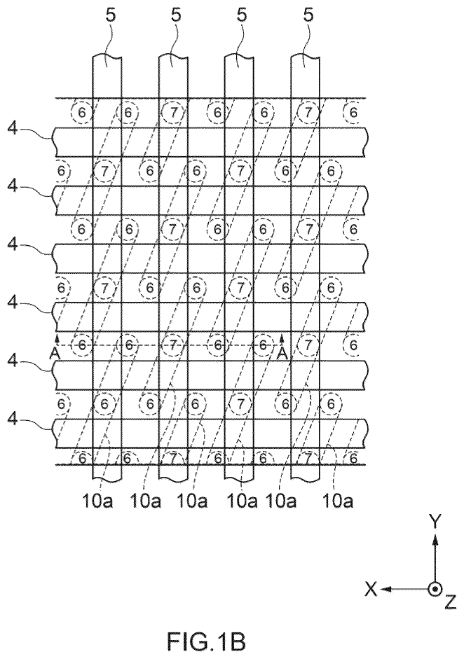

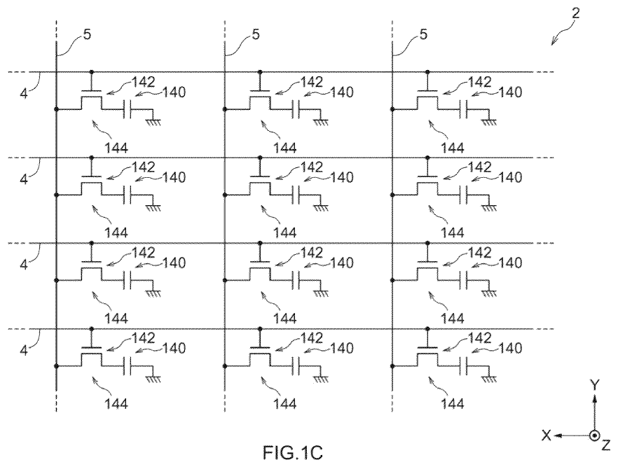

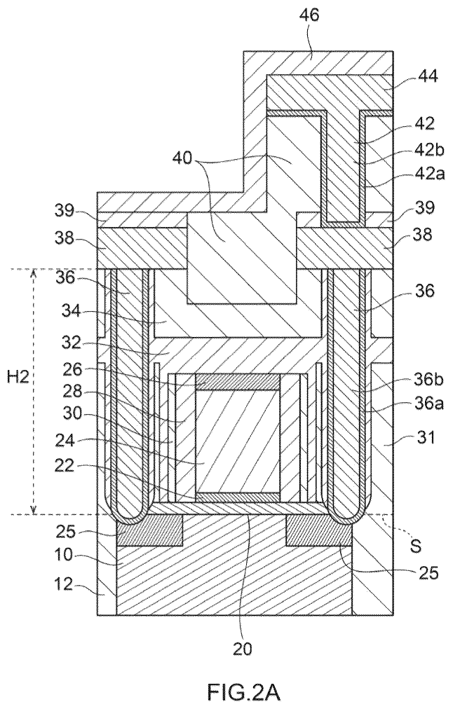

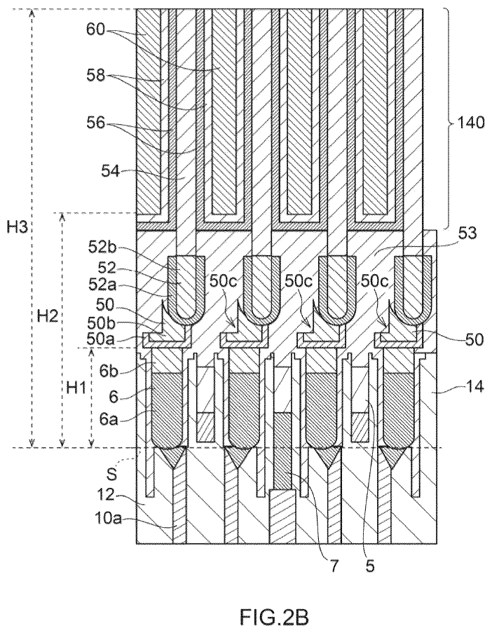

FIG. 1A is a diagram showing a planar layout of the semiconductor device according to the embodiment. As shown in FIG. 1A, the semiconductor device includes a plurality of memory mats 2 arranged in a matrix form on the surface of a semiconductor substrate. Each memory mat 2 has a rectangular shape. A plurality of memory cells are arranged inside the memory mat 2 as shown in FIG. 1B. A schematic configuration of a memory cell region M in FIG. 1A is shown in FIG. 1B, FIG. 2B, etc. described later. A schematic configuration of a peripheral region P of FIG. 1A is shown in FIG. 2A described later.

FIG. 1B shows a schematic configuration of the memory cell region M in FIG. 1A. As shown in FIG. 1B, the memory cell region M includes a plurality of word lines 4 arranged in parallel at equal pitches in the Y-direction, and a plurality of bit lines 5 arranged in parallel at equal pitches in the X-direction, the plurality of word lines 4 and the plurality of bit lines 5 being arranged orthogonally to each other. Each of the word lines 4 extends in the X-direction. Each of the bit lines 5 extends in the Y-direction. A plurality of active regions 10a constituting memory cells are arranged at the intersection points of the respective word lines 4 and the respective bit lines 5.

The active region 10a has an island shape surrounded by an isolation 12, and the longitudinal direction thereof is inclined at a predetermined angle with respect to the bit line 5. The word line 4 functions as a gate electrode of an access transistor of a memory cell provided in the active region 10a. The bit line 5 is connected to planar center portions of the active regions 10a via bit line contacts 7. A capacitor contact 6 is arranged on an opposite side of the word line 4 to the bit line contact 7 in the active region 10a. A memory cell capacitor 140 shown in FIG. 2B, which will be described later, is connected to the capacitor contact 6.

FIG. 1C shows an equivalent circuit of a memory cell array of the semiconductor device according to the embodiment. A plurality of memory cells 144 are connected to the intersection points of the word lines 4 and the bit lines 5 which are arranged orthogonally, and arranged in a matrix form. One memory cell 144 includes a pair of an access transistor 142 and a memory cell capacitor 140. The access transistor 142 is also referred to as a memory cell transistor.

The access transistor 142 includes, for example, a metal-oxide-semiconductor field-effect transistor (MOSFET). In each memory mat 2, a plurality of word lines 4 are arranged in parallel so as to extend in the X-direction in FIG. 1C, and a plurality of bit lines 5 are arranged in parallel so as to extend in the Y-direction in FIG. 1C. A gate electrode of the access transistor 142 functions as a word line 4 of DRAM. A word line 4 functions as a control line for controlling selection of memory cells corresponding to the word line 4. The access transistor 142 includes a source/drain region, or a diffusion region.

One of the source and drain of the access transistor 142 is connected to the corresponding bit line 5, and the other is connected to the memory cell capacitor 140. The memory cell capacitor 140 includes a capacitor, and data is stored by storing charge in the capacitor.

When data is written into the memory cell 144, potential for turning on the access transistor 142 is applied to the word line 4, and low potential or high potential corresponding to write-in data “0” or “1” is applied to the bit line 5. When data is read out from the memory cell 144, potential for turning on the access transistor 142 is applied to the word line 4. As a result, the potential extracted from the memory cell capacitor 140 to the bit line 5 is sensed by a sense amplifier (not shown) connected to the bit line 5, thereby performing determination of the data.

FIG. 2A is a diagram showing a schematic configuration of the semiconductor device 1 according to the embodiment, and is a longitudinal sectional view in a peripheral region P. The peripheral region P is provided with peripheral circuits such as a decoder and an address buffer (not shown). FIG. 2A schematically shows MOSFETs, wirings, etc. to be used in these peripheral circuits. A MOSFET to be used in a peripheral circuit is also referred to as a peripheral transistor.

As shown in FIG. 2A, the semiconductor device 1 includes a semiconductor substrate 10, an isolation 12 provided on the semiconductor substrate 10, a gate electrode 24 provided on the semiconductor substrate 10, peripheral first conductive plugs 36, peripheral first wirings 38, a peripheral second conductive plug 42, and a peripheral second wiring 44. The gate electrode 24 is arranged above the semiconductor substrate 10, and a SiGe film 20 and a gate insulating film 22 are arranged from the surface side of the semiconductor substrate 10 between the gate electrode 24 and the surface of the semiconductor substrate 10. An on-gate insulator 26 is arranged on the gate electrode 24.

The semiconductor substrate 10 includes, for example, silicon single crystal. The isolation 12 is embedded inside the semiconductor substrate 10, and includes, for example, silicon dioxide (SiO₂). The isolation 12 has a function of electrically isolating adjacent elements from each other. The SiGe film 20 includes SiGe. A gate insulating film 22 includes, for example, a laminate of silicon dioxide (SiO₂) and a high-K film such as hafnium oxide. The gate electrode 24 includes, for example, a laminate of conductive materials such as titanium (Ti), titanium nitride (TiN), polysilicon (Poly-Si) doped with an impurity such as phosphorus (P), arsenic (As), or boron (B), and tungsten (W). The on-gate insulator 26 includes, for example, silicon nitride (SiN). The gate electrode 24 functions as a gate electrode of the MOSFET.

A first sidewall insulator 28 and a second sidewall insulator 30 are provided on the sidewalls of the gate electrode 24 and the on-gate insulator 26. The first sidewall insulator 28 includes, for example, silicon nitride, and the second sidewall insulator 30 includes, for example, silicon dioxide. A first interlayer insulator 31 is arranged around the second sidewall insulator 30. The first interlayer insulator 31 includes, for example, silicon dioxide.

The upper part of the on-gate insulator 26 on the gate electrode 24 is covered with the second interlayer insulator 32, and the upper part of the second interlayer insulator 32 is covered with a third interlayer insulator 34.

The peripheral first conductive plugs 36 are arranged on the semiconductor substrate 10 on both sides of the gate electrode 24, and the peripheral first conductive plugs 36 are connected to the upper surface of the semiconductor substrate 10. The semiconductor substrate 10 to which the peripheral first conductive plugs 36 are connected is provided with source/drain regions 25 of the MOSFET, that is, diffusion regions. The peripheral first conductive plugs 36 penetrate the third interlayer insulator 34, the second interlayer insulator 32, and the first interlayer insulator 31. The peripheral first conductive plugs 36 contain a barrier metal 36a and a metal 36b. The barrier metal 36a contains a conductive material, for example, contains titanium nitride. The metal 36b contains a conductive material, for example, contains tungsten.

The peripheral first wiring 38 is provided on the peripheral first conductive plug 36 and the third interlayer insulator 34. The peripheral first wiring 38 is connected to the peripheral first conductive plug 36. The peripheral first wiring 38 contains a conductive material, for example, contains tungsten. An on-wiring insulator 39 is provided on the peripheral first wiring 38. The on-wiring insulator 39 contains an insulator, for example, contains silicon nitride. The on-gate insulator 26, the second interlayer insulator 32, and the third interlayer insulator 34 are provided between the gate electrode 24 and the peripheral first wiring 38.

The peripheral second conductive plug 42 and the peripheral second wiring 44 are provided on the peripheral first wiring 38. The peripheral second conductive plug 42 is connected to the upper surface of the peripheral first wiring 38. A barrier metal 42a is provided at the bottom and side portions of the peripheral second conductive plug 42 and at the bottom portion of the peripheral second wiring 44. The barrier metal 42a contains a conductive material, for example, contains titanium nitride. A metal 42b and the peripheral second wiring 44 contain a conductive material, for example, contain tungsten. The peripheral second conductive plug 42 and the peripheral second wiring 44 are configured integrally with each other.

A fourth interlayer insulating portion 40 is provided between the adjacent peripheral first wirings 38, around the peripheral second conductive plug 42, and below the peripheral second wiring 44. The fourth interlayer insulating portion 40 contains an insulator, for example, contains silicon dioxide. An upper insulator 46 is provided so as to cover the peripheral first wiring 38 containing the on-wiring insulator 39 and the peripheral second wiring 44. The upper insulator 46 contains an insulator, for example, contains silicon nitride. The peripheral first wiring 38 is provided on the third interlayer insulator 34, whereby the distance between the gate electrode 24 and the peripheral first wiring 38 increases, so that it is possible to reduce parasitic capacitance between the gate electrode 24 and the peripheral first wiring 38. Furthermore, it is possible to suppress short-circuiting between the gate electrode 24 and the peripheral first wiring 38.

As shown in FIG. 2B, the semiconductor device 1 includes active regions 10a provided in the semiconductor substrate 10, an isolation 12, capacitor contacts 6, a bit line contact 7, first connection electrodes 50, second connection electrodes 52, and memory cell capacitors 140. An interlayer insulating film 14 is provided around the capacitor contact 6. The capacitor contact 6 and the bit line contact 7 are connected to the active region 10a. The first connection electrode 50 and the second connection electrode 52 serve as a redistribution structure that connects the capacitor contact 6 and the memory cell capacitor 140.

The first connection electrode 50 is connected to the capacitor contact 6, and the second connection electrode 52 is connected to the first connection electrode 50. The second connection electrode 52 is electrically and physically connected to the upper surface of the first connection electrode 50. The second connection electrode 52 is connected at a position which is shifted to the right from the center of the first connection electrode 50 in the left-right direction. The center of the bottom surface of the second connection electrode 52 and the center of the top surface of the first connection electrode 50 are shifted from each other. A shoulder portion of the first connection electrode 50 in a region where the second connection electrode 52 is not connected to the first connection electrode 50, that is, a shoulder portion on the left side of the first connection electrode 50 is missing, and forms a chipped portion 50c. The second connection electrode 52 is not arranged above the chipped portion 50c.

The memory cell capacitor 140 is connected to the second connection electrodes 52. A fifth interlayer insulator 53 is provided around the first connection electrodes 50 and the second connection electrodes 52. As described above, the active region 10a and the memory cell capacitor 140 are connected to each other by the three connection portions of the capacitor contact 6, the first connection electrode 50, and the second connection electrode 52.

The capacitor contact 6 includes a lower electrode 6a and an upper electrode 6b. The lower electrode 6a contains a conductive material, for example, contains polysilicon doped with impurities such as phosphorus, and the upper electrode 6b contains a conductive material, for example, contains cobalt silicide (CoSi). The interlayer insulating film 14 and the fifth interlayer insulator 53 contain an insulator, for example, contain silicon dioxide.

The first connection electrode 50 contains a barrier metal 50a and a metal 50b. The second connection electrode 52 contains a barrier metal 52a and a metal 52b. The barrier metals 50a and 52a contain a conductive material, for example, contain titanium nitride. The metals 50b and 52b contain a conductive material, for example, contain tungsten.

The memory cell capacitor 140 includes a lower electrode 54, a capacitive insulating film 56, an upper electrode 58, and a plate electrode 60. The lower electrode 54 is connected to the second connection electrode 52. The capacitive insulating film 56 is interposed between the lower electrode 54 and the upper electrode 58. The lower electrode 54, the capacitive insulating film 56, and the upper electrode 58 constitute a capacitor. The upper electrode 58 is connected to the plate electrode 60.

The lower electrode 54 and the upper electrode 58 contain a conductive material, for example, contain titanium nitride. The capacitive insulating film 56 contains an insulator, for example, contains a high-K film such as hafnium oxide. The plate electrode 60 contains a conductive material, for example, contains polysilicon doped with impurities such as phosphorus.

In FIG. 2A and FIG. 2B, a substrate surface position S indicates the position of the upper surface of the semiconductor substrate 10, and the substrate surface positions S in FIG. 2A and FIG. 2B are matched with each other. The following heights H1 to H3 indicate heights based on the substrate surface position S. The height of the upper surface of the capacitor contact 6, that is, the height H1 of the lower surface of the first connection electrode 50 is lower than the height H2 of the peripheral first conductive plug 36, that is, the lower surface of the peripheral first wiring 38. The height H2 of the lower surface of the peripheral first wiring 38 is higher than the height H1 of the lower surface of the lower electrode 54 of the memory cell capacitor 140, and also lower than the height H3 of the upper surface of the lower electrode 54. The peripheral first wiring 38 and the lower electrode 54 of the memory cell capacitor 140 are located at heights where they overlap each other. The first connection electrode 50 is arranged on the capacitor contact 6, and the peripheral first wiring 38 is arranged on the peripheral first conductive plug 36.

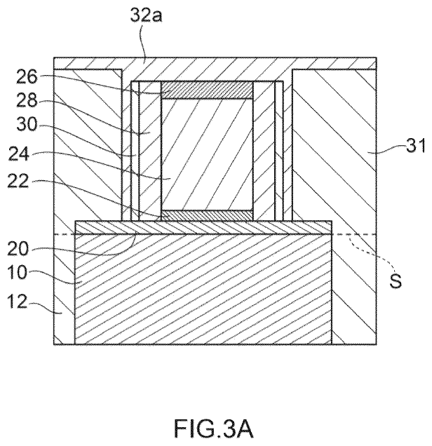

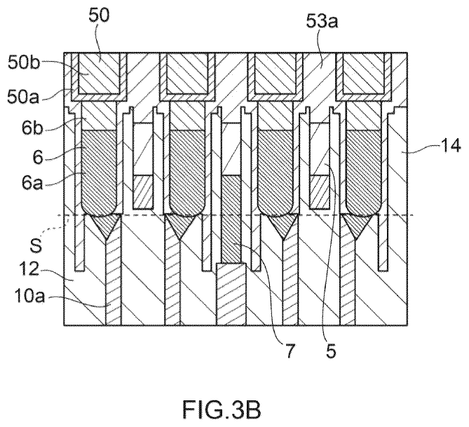

Next, a method for manufacturing the semiconductor device 1 according to the embodiment will be described. First, as shown in FIG. 3A, the SiGe film 20, the gate insulating film 22, the gate electrode 24, the on-gate insulator 26, the first sidewall insulator 28, the second sidewall insulator 30, and the first interlayer insulator 31 are formed on the semiconductor substrate 10 in the peripheral region P. The isolation 12 is formed on the semiconductor substrate 10. The tops of the on-gate insulator 26 and the first interlayer insulator 31 are covered with a lower insulator 32a. The first interlayer insulator 31 is formed on the semiconductor substrate 10 and around the gate electrode 24, the first sidewall insulator 28, and the second sidewall insulator 30.

Furthermore, as shown in FIG. 3B, the bit lines 5, the capacitor contacts 6, the bit line contact 7, and the first connection electrodes 50 are formed on the semiconductor substrate 10 in the memory cell region M. The active regions 10a are formed in the semiconductor substrate 10. The interlayer insulating film 14 is formed on the semiconductor substrate 10 and around the capacitor contacts 6. An insulator 53a is formed on the interlayer insulating film 14 and around the first connection electrodes 50. The upper surfaces of the first connection electrodes 50 and the upper surface of the insulator 53a constitute the same plane. The upper surfaces of the first connection electrodes 50 are exposed. The other configurations are the same as those described with reference to FIG. 2A and FIG. 2B.

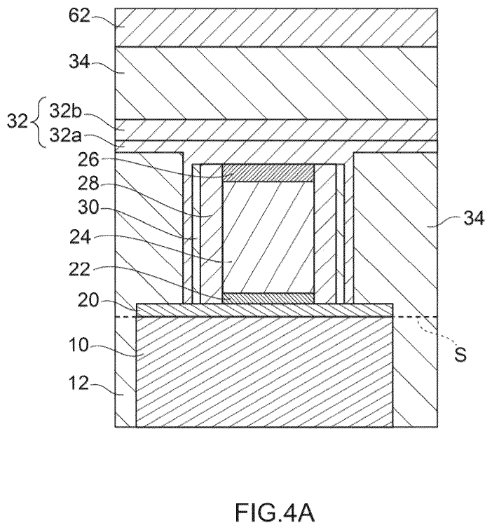

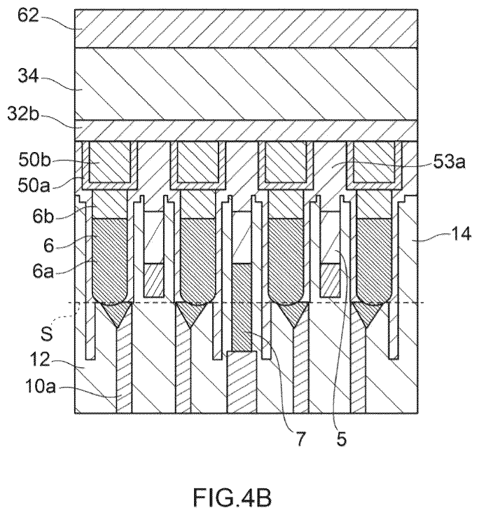

Next, as shown in FIGS. 4A and 4B, an upper insulator 32b, the third interlayer insulator 34, and a sacrificial insulating film 62 are formed so as to cover the upper surface of the lower insulator 32a in FIG. 4A showing the configuration of the peripheral region P, and so as to cover the upper surfaces of the first connection electrodes 50 and the insulator 53a in FIG. 4B showing the configuration of the memory cell region M. The upper insulator 32b contains an insulator, for example, contains silicon nitride. Here, since the lower insulator 32a and the upper insulator 32b contain silicon nitride, it is difficult to identify the boundary therebetween, and further they are substantially integrated with each other. Therefore, they are collectively referred to as a second interlayer insulator 32. The third interlayer insulator 34 contains an insulator, for example, contains silicon dioxide. The sacrificial insulating film 62 contains an insulator, for example, contains silicon nitride. The films of the upper insulator 32b, the third interlayer insulator 34, and the sacrificial insulating film 62 are formed, for example, by using a chemical vapor deposition (CVD) technique.

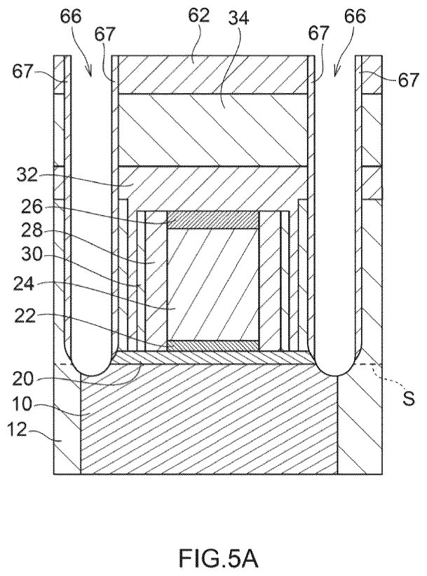

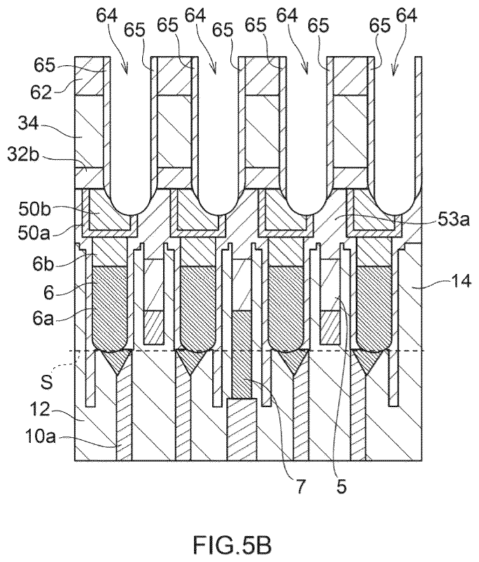

Next, as shown in FIG. 5A and FIG. 5B, contact holes 66 and sidewalls 67 are formed in FIG. 5A, and contact holes 64 and sidewalls 65 are formed in FIG. 5B. A step in FIG. 5A and a step in FIG. 5B are performed as separate steps as described below.

First, the step in FIG. 5B will be described. A contact hole 64 to be connected to the first connection electrodes 50 are formed. The contact holes 64 are formed by using a well-known lithography technique and a well-known anisotropic dry etching technique. During this step, the peripheral region P shown in FIG. 5A is covered with a resist. Next, an insulating film is formed to cover the inner surfaces of the contact holes 64 and the upper surface of the sacrificial insulating film 62. This insulating film contains, for example, silicon nitride, and is formed by using, for example, a well-known atomic layer deposition (ALD) technique. Next, the insulating film is etched back using anisotropic dry etching until the insulating film on the upper surface of the sacrificial insulating film 62 has been removed. This etch-back also removes the insulating film on the bottom surfaces of the contact holes 64, and sidewalls 65 of the insulating film are formed only on the sidewalls of the contact holes 64.

Next, the step in FIG. 5A will be described. Contact holes 66 are formed to open the surface of the semiconductor substrate 10 located on both sides of the gate electrode 24. The contact holes 66 are formed using a well-known lithography technique and a well-known anisotropic dry etching technique. During this step, the memory cell region M shown in FIG. 5B is covered with a resist. Next, an insulating film is formed to cover the inner surfaces of the contact holes 66 and the upper surface of the sacrificial insulating film 62. This insulating film contains, for example, titanium nitride, and is formed by using, for example, the ALD technique. Next, this insulator is etched back by using the anisotropic dry etching until the insulating film on the upper surface of the sacrificial insulating film 62 has been removed. This etch-back also removes the insulating film on the bottom surfaces of the contact holes 66, and sidewalls 67 of the insulating film are formed only on the sidewalls of the contact holes 66.

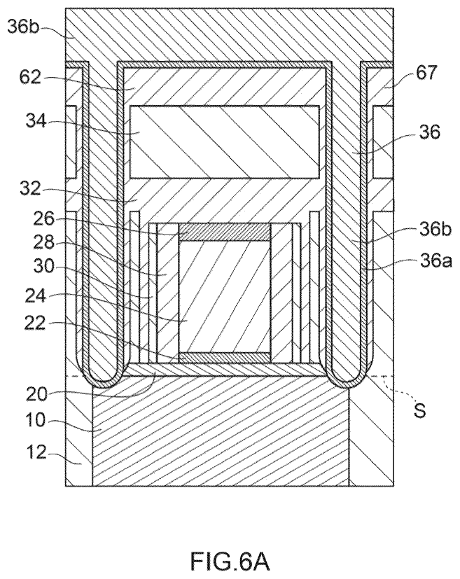

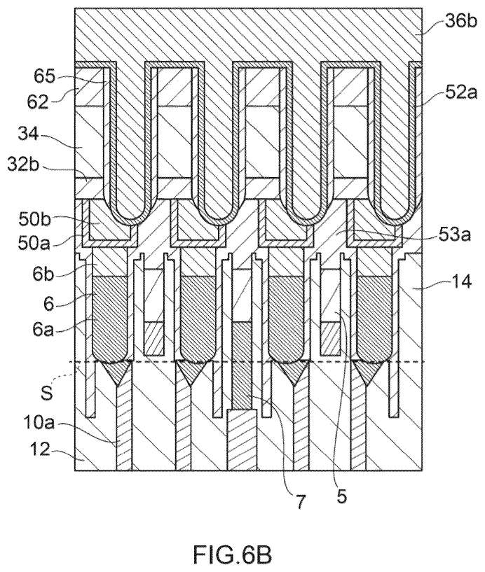

Next, as shown in FIG. 6A and FIG. 6B, films of the barrier metal 36a and the metal 36b are formed so as to be embedded in the contact holes 64 and 66 and cover the upper surface of the sacrificial insulating film 62. The barrier metal 36a contains a conductive material, for example, contains titanium nitride. The metal 36b contains a conductive material, for example, contains tungsten. The films of the barrier metal 36a and the metal 36b are formed by using, for example, a CVD technique.

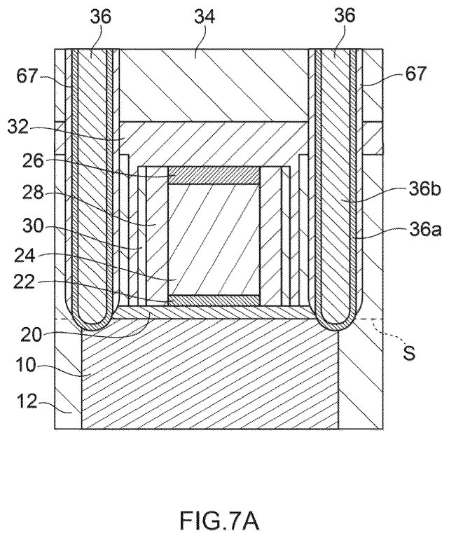

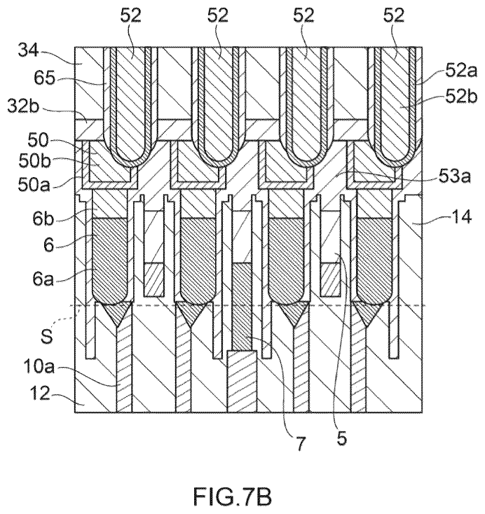

Next, as shown in FIG. 7A and FIG. 7B, chemical mechanical polishing (CMP) is performed to polish and remove the metal 36b and barrier metal 52a until the upper surface of the third interlayer insulator 34 is exposed. As a result, the remaining barrier metal 36a and metal 36b serve as the peripheral first conductive plugs 36 in the peripheral region P shown in FIG. 7A. Furthermore, in the memory cell region M shown in FIG. 7B, the remaining barrier metal 36a and metal 36b serve as the second connection electrodes 52. Here, the remaining barrier metal 36a and metal 36b are referred to as a barrier metal 52a and a metal 52b. In the peripheral region P, the upper surfaces of the peripheral first conductive plugs 36 and the upper surface of the third interlayer insulator 34 constitute the same plane. In the memory cell region M, the upper surfaces of the second connection electrodes 52 and the upper surface of the third interlayer insulator 34 constitute the same plane.

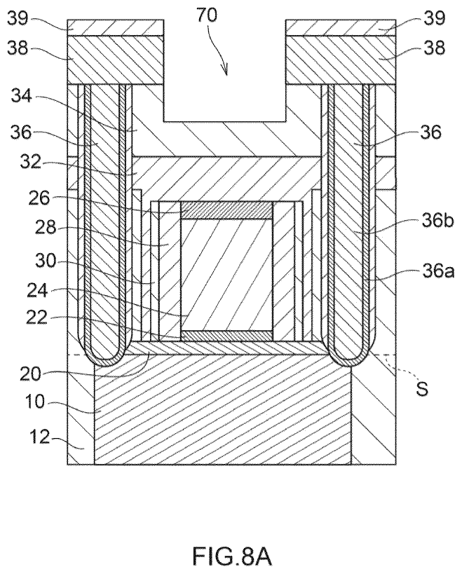

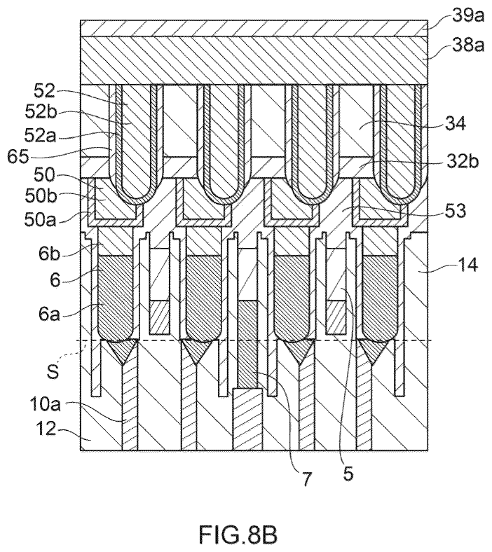

Next, as shown in FIG. 8A and FIG. 8B, a metal film 38a and an insulating portion 39a are formed in the peripheral region P and the memory cell region M. The metal film 38a contains a conductive material, for example, contains tungsten. The insulating portion 39a contains an insulator, for example, contains silicon nitride. The metal film 38a and the insulating portion 39a are formed by using, for example, a CVD technique. Next, the metal film 38a and the insulating portion 39a in the peripheral region P are processed by using a well-known lithography technique and the anisotropic dry etching technique. The metal film 38a and the insulating portion 39a in the peripheral region P are processed, and serve as the peripheral first wiring 38 and the on-wiring insulator 39 on the peripheral first wiring 38. A recess portion 70 is formed in the third interlayer insulator 34 between the peripheral first wirings 38.

In this step, the memory cell region M shown in FIG. 8B is covered with a resist, and is not processed in this step. Through this step, in the peripheral region P, the peripheral first conductive plugs 36, connected to the source/drain regions 25 of the MOSFET whose gate electrode is the gate electrode 24, and the peripheral first wirings 38 are formed.

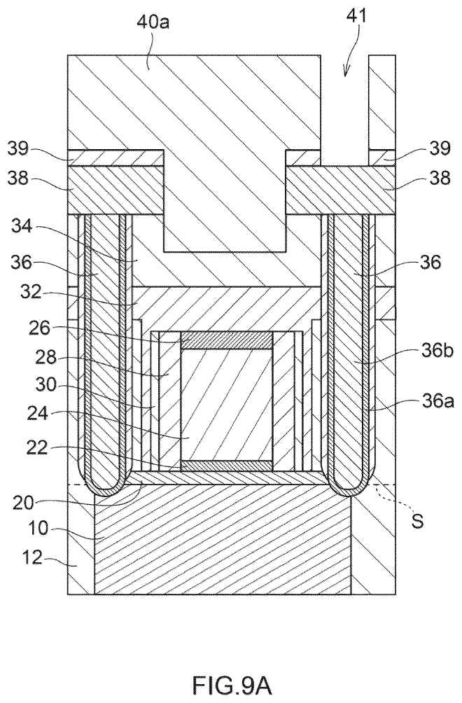

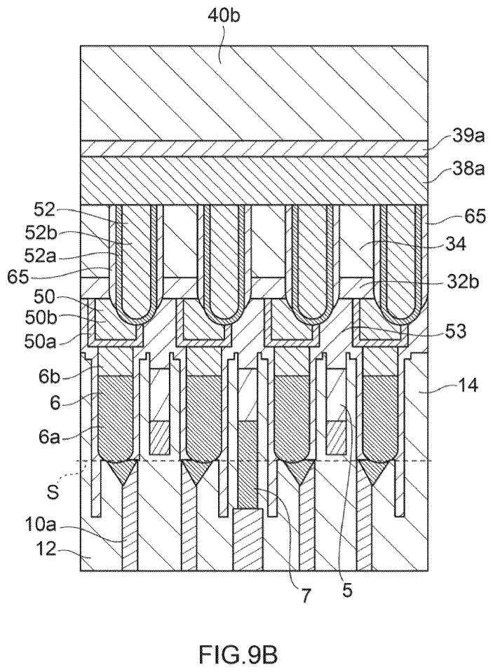

Next, as shown in FIG. 9A and FIG. 9B, an insulator 40a is formed in the peripheral region P and the memory cell region M. The insulator 40a contains an insulator, for example, contains silicon dioxide. The insulator 40a is formed by using, for example, a CVD technique. Next, the insulator 40a and the on-wiring insulator 39 are etched using a well-known lithography technique and a well-known anisotropic dry etching technique to form a contact hole 41 that reaches the upper surface of the peripheral first wiring 38. In this step, the memory cell region M shown in FIG. 9B is covered with a resist, and is not processed in this step.

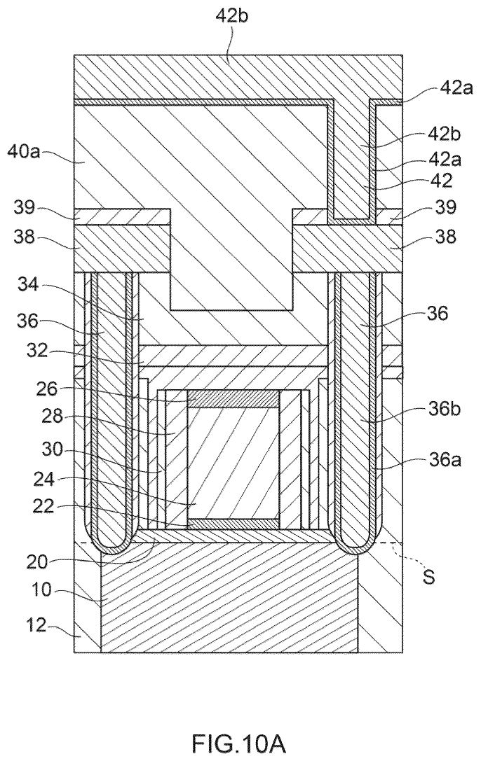

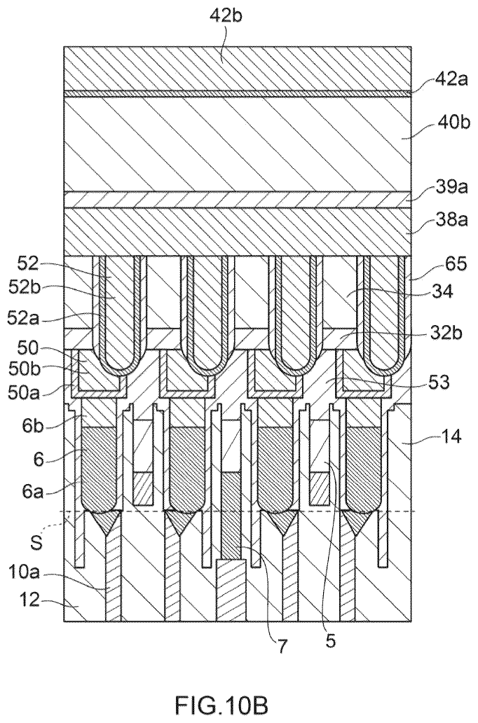

Next, as shown in FIG. 10A and FIG. 10B, the barrier metal 42a and the metal 42b are formed in the peripheral region P and the memory cell region M. The barrier metal 42a and the metal 42b are formed to be embedded in the contact hole 41 and cover the upper surface of the insulator 40a. The barrier metal 42a contains a conductive material, for example, contains titanium nitride, and the metal 42b contains a conductive material, for example, contains tungsten. The barrier metal 42a and the metal 42b are formed by using, for example, a CVD technique.

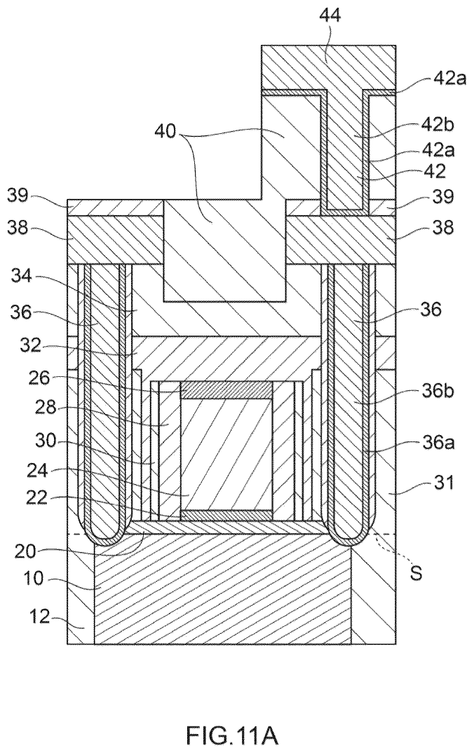

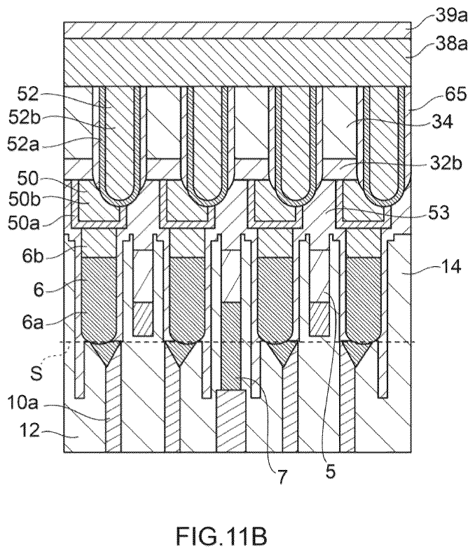

Next, as shown in FIG. 11A and FIG. 11B, the metal 42b and the barrier metal 42a are etched by using well-known lithography technique and anisotropic dry etching technique, and the insulator 40a is further etched until the upper surface of the on-wiring insulator 39 is exposed. As a result, the peripheral second wiring 44 and the peripheral second conductive plug 42 are formed. The remaining insulator 40a serves as the fourth interlayer insulating portion 40. In this step, since no resist is formed on the memory cell region M shown in FIG. 11B, the metal 42b, the barrier metal 42a, and the insulator 40a are removed by etching, so that the upper surface of the on-wiring insulator 39 is exposed.

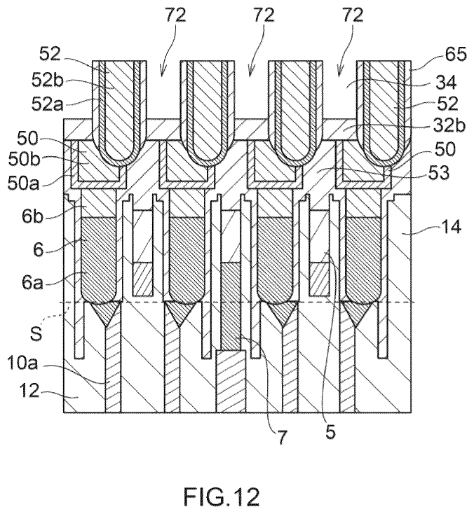

Next, as shown in FIG. 12, in the memory cell region M, a resist (not shown) is formed in regions other than the memory cell region M by using a well-known lithography technique. A well-known dry etching technique is performed while this resist is used as a mask, thereby sequentially etching and removing the insulating portion 39a, the metal film 38a, and the third interlayer insulator 34 in the memory cell region M. In this dry etching, each of anisotropic dry etching and isotropic dry etching can be used. By removing the third interlayer insulator 34, the upper surface of the upper insulator 32b is exposed, so that recess portions 72 are formed between adjacent second connection electrodes 52.

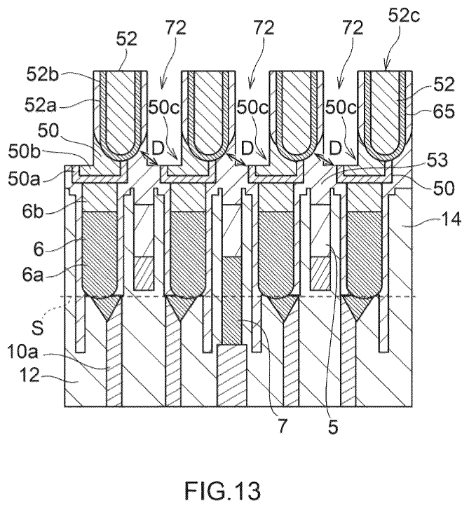

Note that in the steps shown in FIGS. 12 and 13, the peripheral region P is covered with a resist. Therefore, no processing is performed in the peripheral region P. Therefore, since there is no change from FIG. 11A in the peripheral region P, Figure showing the configuration of the peripheral region P is omitted.

Next, as shown in FIG. 13, anisotropic dry etching is performed in the memory cell region M to remove the upper insulator 32b. Furthermore, a part of the first connection electrode 50 is removed by etching, and then the resist is removed. This etching is performed under a condition that the etching rates of the materials constituting the second connection electrodes 52, the first connection electrodes 50, the sidewalls 65, and the fifth interlayer insulator 53 are approximately equal to one another. In other words, this etching is performed under a condition that the etching rates of titanium nitride, tungsten, silicon dioxide, and silicon nitride are approximately equal to one another.

The second connection electrodes 52 are also etched in the up-and-down direction by this etching, so that the heights of the second connection electrodes 52 in the up-and-down direction are reduced, which causes the second connection electrodes 52 to be lower in height. This etching removes the bottom portions of the recess portions 72, that is, parts of the shoulder portions of the first connection electrodes 50 which do not overlap the second connection electrodes 52 in the up-and-down direction, thereby forming the chipped portions 50c. Therefore, the distance D between the first connection electrode 50 and the second connection electrode 52 connected to the first connection electrode 50 adjacent to the above first connection electrode 50 increases, so that it is possible to suppress short-circuiting between the first connection electrode 50 and the second connection electrode 52 adjacent to the above first connection electrode 50. Furthermore, the second connection electrodes 52 are not etched in the left-right direction by the above etching. Therefore, opening between the first connection electrode 50 and the second connection electrode 52 is suppressed.

Next, as shown in FIG. 2A and FIG. 2B, in the memory cell region M, an insulator is formed so as to be embedded in the recess portions 70 and cover the upper portions of the first connection electrodes 50. This insulator contains, for example, silicon nitride. This insulator serves as a part of the fifth interlayer insulator 53. Next, the memory cell capacitors 140 connected to the first connection electrodes 50 are formed. In the peripheral region P, as shown in FIG. 2A, the on-wiring insulator 39, the fourth interlayer insulating portion 40, and the upper insulator 46 covering the peripheral second wiring 44 are formed. Through the above steps, the semiconductor device 1 according to the embodiment is formed.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a memory cell capacitor;
a memory cell transistor having diffusion regions;
a redistribution structure coupled between one of the diffusion regions of the memory cell transistor and the memory cell capacitor;
a first wiring;
a peripheral transistor having diffusion regions; and
a contact plug connected between one of the diffusion regions of the peripheral transistor and the first wiring;
wherein the first wiring is on a layer higher than that the redistribution structure is on.

2. The apparatus of claim 1, wherein the redistribution structure comprises a lower portion and an upper portion connected to an upper surface of the lower portion.

3. The apparatus of claim 2, wherein a center of a bottom surface of the lower portion of the redistribution structure and a center of an upper surface of the upper portion of the redistribution structure are shifted from each other.

4. The apparatus of claim 3, wherein the lower portion includes a chipped portion.

5. The apparatus of claim 2, further comprising a memory cell contact plug sandwiched between the redistribution structure and one of the diffusion regions of the memory cell transistor.

6. The apparatus of claim 1, wherein the peripheral transistor has a gate electrode, the apparatus further comprises:
a first insulating film including a first material; and
a second insulating film including a second material;
wherein both of the first insulating film and the second insulating film are between the gate electrode and the first wiring.

7. The apparatus of claim 6, wherein the first insulating film includes silicon nitride and the second insulating film includes silicon dioxide.

8. The apparatus of claim 1, wherein the first wiring includes titanium nitride and tungsten, and the contact plug includes tungsten.

9. An apparatus comprising:
a memory cell capacitor;
a memory cell transistor having diffusion regions;
a redistribution structure coupled between one of the diffusion regions of the memory cell transistor and the memory cell capacitor;
a first wiring;
a peripheral transistor having diffusion regions; and
a contact plug connected between one of the diffusion regions of the peripheral transistor and the first wiring;
wherein the first wiring is on a layer partially overlapping with the memory cell capacitor.

10. The apparatus of claim 9, wherein the redistribution structure comprises a lower portion and an upper portion connected to an upper surface of the lower portion.

11. The apparatus of claim 10, wherein a center of a bottom surface of the lower portion of the redistribution structure and a center of an upper surface of the upper portion of the redistribution structure are shifted from each other.

12. The apparatus of claim 10, wherein the lower portion includes a chipped portion.

13. The apparatus of claim 10, further comprising a memory cell contact plug sandwiched between the redistribution structure and one of the diffusion regions of the memory cell transistor.

14. The apparatus of claim 9, wherein the peripheral transistor has a gate electrode, the apparatus further comprises:
a first insulating film including a first material; and
a second insulating film including a second material;
wherein both of the first insulating film and the second insulating film are between the gate electrode and the first wiring.

15. The apparatus of claim 14, wherein the first insulating film includes silicon nitride and the second insulating film includes silicon dioxide.

16. The apparatus of claim 9, wherein the first wiring includes titanium nitride and tungsten, and the contact plug includes tungsten.

17. A method comprising:
forming a first electrode electrically and physically connected to an active region provided in a memory cell region;
forming a second electrode connected to a portion of an upper surface of the first electrode;
etching the second electrode and the first electrode proceeding only in a vertical direction, thereby reducing a height of the second electrode, and forming a chipped portion on a portion of the first electrode in a region the second electrode is not connected.

18. The method of claim 17, wherein the first electrode comprises titanium nitride and tungsten.

19. The method of claim 17, wherein the second electrode comprises titanium nitride and tungsten.

20. The method of claim 17, wherein anisotropic dry etching is performed in the etching.
